(19) United States
(12) Patent Application Publication
(10) Pub. No.: US 2004/0184303 A1
(43) Pub. Date: Sep. 23, 2004

(54) Memory circuit and method for operating the same

(75) Inventor: Takashi Manabe, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: NEC PLASMA DISPLAY CORPORATION

(21) Appl. No.: 10/814,268

(22) Filed: Apr. 1, 2004

(30) Foreign Application Priority Data
Jan. 4, 2003 (JP) 2003-098175

(51) Int. Cl. G11C 11/21

(52) U.S. Cl. 365/123

(57) ABSTRACT

A memory circuit includes a delay circuit for generating a delay clock signal by delaying a reference clock signal, a temperature detection circuit, and a voltage detection circuit. The temperature detection circuit detects the temperature of part around a memory and the voltage detection circuit detects the power-supply voltage of the memory. The delay circuit determines the delay amount of the delay clock signal according to at least one of temperature data detected by the temperature detection circuit and voltage data detected by the voltage detection circuit, whereby a circuit accessing the memory can supply a clock signal without being affected by the temperature change and/or the power-supply voltage fluctuation.

### BACKGROUND OF THE INVENTION

1. Field of the Invention

The present invention relates to a memory circuit having an improved memory access circuit and a method for operating the memory circuit.

2. Description of the Related Art

For designing a memory access circuit, it is difficult to correctly estimate the delay of data of an external memory. For example, the data cycle of a DDR SDRAM that is a dominating DRAM and that operates at 166 MHz is as short as 3 ns. Further, timing change as much as about 2 ns may occur due to the process difference between the DDR SDRAM and the memory access circuit, variations in the electric constant of a board connecting the DDR SDRAM and the memory access circuit, the operation temperature change, and the power-supply voltage change.

Where the memory delay and the wiring delay of a substrate are changed from what they were when an LSI including the memory access circuit was designed, the LSI may fail to function normally and suffer a poor operation margin. For solving the above-described problems, a circuit configuration that can change the clock-signal delay is used.

Hitherto, the technology for obtaining a clock signal of a circuit has been known, where a plurality of delay buffers is connected to a clock signal line and the number of buffers is changed according to an external control signal (for example, see Japanese Unexamined Patent Application Publication No. 2000-91506).

FIG. 1 illustrates an example memory access circuit using the above-described technology, where this memory access circuit is used for reading and writing a memory. A clock original signal is generated in a clock generation circuit 3 and supplied to a memory 7 and a memory access circuit 18 through a signal line 10. This clock original signal drives the memory 7 and is input to the memory access circuit 18. Further, the clock original signal is delayed by a plurality of delay buffers 4 of a delay circuit 6 and supplied to a data-capture flip-flop circuit 8 via a signal line 11, as a read clock signal. A data signal from the memory 7 is supplied to the data-capture flip-flop circuit 8 via a signal line 9. The delay amount of the delay circuit 6 is selected by a selection circuit 5. This selection circuit 5 is controlled by an external switch 20 connected thereto via a signal line 12.

In the above-described memory access circuit, the read clock signal input to the data-capture flip-flop circuit 8 for capturing data from the memory 7 is delayed with reference to the clock original signal for driving the memory 7. This read clock signal is delayed by the delay circuit 4 and the delay amount of the read clock signal can be switched by an external switch 20.

However, according to the above-described configuration, where the suitable delay amount changes due to some reasons during the memory access circuit is operating, the memory access circuit may fail to operate correctly. For example, the delay amount of the delay circuit 4 changes, as the temperature and/or power-supply voltage around the memory access circuit changes. Subsequently, a predetermined delay amount cannot be obtained. In this case, the operation temperature range is limited and the operation voltage range is decreased, for example. Particularly, where a high-speed memory is used, these operation ranges are significantly limited by the delay-amount voltage. For example, where the memory 7 operates at 333 MHz, the data cycle thereof is as short as 3 ns and the delay-amount fluctuation due to the temperature change is as large as 2 ns. Subsequently, the operation margin of the memory access circuit is significantly reduced.

Particularly, a large display device such as a recently developed plasma display requires a high-speed and large capacity DRAM and a signal processing LSI using high-technology processes.

The temperature of a panel of the plasma display changes from 10 degrees Celsius below zero to 80 degrees Celsius, and the panel driving voltage is as high as ±180 V. Here, the above-described DDR SDRAM and LSI operate at a low voltage of about 2.5 V and are significantly affected by the panel temperature change and the operation voltage change.

### SUMMARY OF THE INVENTION

Accordingly, it is an object of the present invention to provide a memory access circuit for supplying a clock signal without being affected by the temperature change or power-supply voltage fluctuation and increasing the operation temperature range and/or the operation voltage range of a device having the memory access circuit mounted thereon (a PDP module or the like).

Features of the present invention will be described as follows using the reference numerals of the embodiments in the parenthesis. A memory circuit (2) according to the present invention comprises a memory (7), a delay circuit (6) for generating delay clock signals (11, 21) by delaying a reference clock signal (10), at least one detection circuits (15, 17) for detecting temperature data (14) of the memory (7) or therearound, and power-supply voltage data (16) of the memory (7) or therearound, and a control circuit (13) for generating a control signal (12) according to the temperature data (14) or the power-supply voltage data (16) detected by the detection circuits (15, 17). The delay circuit (6) controls the delay amount of the delay clock signals (11, 21) by the control signal (12).

The memory circuit (2) further comprises a data capture circuit (8) for capturing data (9) read from the memory (7) and/or data (9) written into the memory (7). The memory (7) and/or the data capture circuit (8) operate(s) in synchronization with the delay clock signals (11, 21).

The delay circuit (6) is formed as a PLL circuit (19) or a DLL circuit (19).

Image data output from the memory circuit (2) is displayed by a display device.

The display device includes the memory circuit (2) and a plasma display panel (1). This plasma display panel (1) displays image data output from the memory circuit (2).

The memory circuit (2) operates according to a method comprising the steps of generating the delay clock signals (11, 21) by delaying the reference clock signal (10), detecting the temperature and/or power-supply voltage of the memory (7), and determining the delay amount of the delay clock signals (11, 21) according to the detected temperature data (14) and/or the detected power-supply voltage (16).

A method according to the present invention is for operating the memory circuit (2) including the memory (7), a first clock, and a second clock is provided. This method comprises the steps of driving the memory (7) in synchronization with the first clock, capturing data read from the memory (7) and/or data written into the memory (7) in synchronization with the second clock, detecting the temperature and/or power-supply voltage of the memory (7) or therearound, and controlling a relative delay amount between the first clock and the second clock according to the detected temperature and/or the detected power-supply voltage.

The memory circuit (2) has the delay circuit (6) for generating the delay clock signals (11, 21) by delaying the reference clock signal (10) and the temperature detection circuit (15). The temperature detection circuit (15) detects the temperature around the memory (7) and the delay circuit (6) determines the delay amount of the delay clock signals (11, 21) according to the temperature data (14) detected by the temperature detection circuit (15).

The memory circuit (2) comprises the control circuit (13) for generating a control signal according to the temperature data (14) detected by the temperature detection circuit (15) and determining the delay amount of the delay clock signals (11, 21) by the control signal.

The memory circuit (2) comprises the delay circuit (6) for generating the delay clock signals (11, 21) by delaying the reference clock signal (10) and the voltage detection circuit (17). This voltage detection circuit (17) detects the power-supply voltage of the memory circuit (2) and the delay circuit (6) determines the delay amount of the delay clock signals (11, 21) by the power-supply voltage data (16) detected by the voltage detection circuit (17).

The memory circuit (2) has the control circuit (13) for generating the control signal according to the power-supply voltage (16) detected by the voltage detection circuit (17). The delay circuit (6) determines the delay amount of the delay clock signals (11, 21) according to the control signal.

The memory circuit (2) includes the delay circuit (6) for generating the delay clock signals (11, 21) by delaying the reference clock signal (10), the temperature detection circuit (15), and the voltage detection circuit (17). The temperature detection circuit (15) detects the temperature around the memory (7). The voltage detection circuit (17) detects the power-supply voltage of the memory (7), and the delay circuit (6) determines the delay amount of the delay clock signals (11, 21), based on the temperature data (14) detected by the temperature detection circuit (15) and the power-supply voltage data (16) detected by the voltage detection circuit (17).

The memory circuit (2) has the control circuit (13) for generating the control signal according to the temperature data (14) detected by the temperature detection circuit (15) and the power-supply voltage data (16) detected by the voltage detection circuit (17). The delay circuit (6) determines the delay amount of the delay clock signals (11, 21) according to the control signal.

The delay circuit (6) is formed as the PLL circuit.

The delay circuit (6) is formed as the DLL circuit.

The memory circuit (2) operates according to a method comprising the steps of generating the delay clock signals (11, 21) by delaying the reference clock signal (10), detecting the temperature of part around the memory (7), and determining the delay amount of the delay clock signals (11, 21) according to the detected temperature data (14).

The memory circuit (2) operates according to a method comprising the steps of generating the delay clock signals (11, 21) by delaying the reference clock signal (10), detecting the power-supply voltage of the memory (7), and determining the delay amount of the delay clock signals (11, 21) according to the detected power-supply voltage (16).

The memory circuit (2) operates according to a method comprising the steps of generating the delay clock signals (11, 21) by delaying the reference clock signal (10), detecting the temperature of the memory (7), detecting the power-supply voltage of the memory (7), and determining the delay amount of the delay clock signals (11, 21) according to the detected temperature and power-supply voltage.

The present invention allows for designing a memory circuit that can access a memory without changing the operation margin thereof, where the temperature and/or power-supply voltage thereof changes during operation. This memory circuit can be effectively used for a circuit with a tight operation margin, such as a circuit using a high-speed memory.

Further, where the memory circuit of the present invention is mounted on a large display device such as a plasma display, the operation temperature range and operation voltage range of the device increase.

### BRIEF DESCRIPTION OF THE DRAWINGS

FIG. 1 illustrates the configuration of a known memory access circuit;

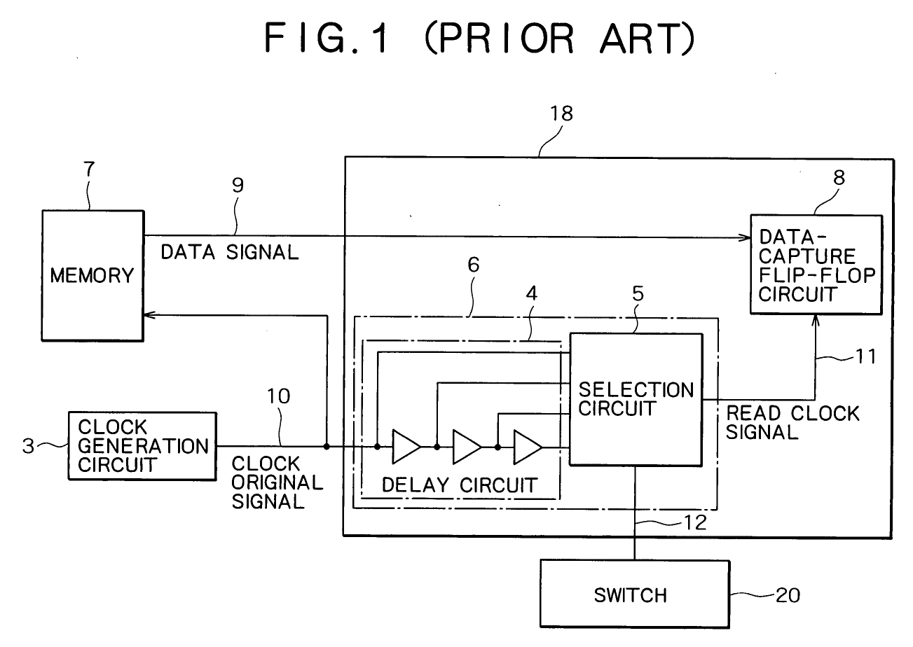

FIG. 2 illustrates a device having a circuit according to a first embodiment of the present invention mounted thereon;

FIG. 3 illustrates an operation for reading a memory performed in the circuit of the first embodiment, where a clock signal input to a data-capture flip-flop circuit is delayed with reference to a clock original signal input to the memory;

FIG. 4 illustrates an operation for writing into the memory performed in the circuit of the first embodiment, where the clock signal input to the data-capture flip-flop circuit is delayed with reference to the clock original signal input to the memory;

FIG. 5 illustrates an operation for reading the memory performed in a circuit according to a second embodiment of the present invention, where the clock signal input to the memory is delayed with reference to the clock original signal input to the data-capture flip-flop circuit;

FIG. 6 illustrates an operation for writing into the memory performed in the circuit according to the second embodiment, where the clock signal input to the memory is delayed with reference to the clock original signal input to the data-capture flip-flop circuit;

FIG. 7 illustrates the read clock signal timing of the present invention, where the stage number of at least one delay element is changed according to temperature;

FIG. 8 illustrates an operation for reading the memory performed in a circuit according to a third embodiment of the present invention, where the clock signal input to the data-capture flip-flop circuit is delayed with reference to the clock original signal input to the memory;

FIG. 9 illustrates an operation for writing into the memory performed in the circuit of the third embodiment, where the clock signal input to the data-capture flip-flop circuit is delayed with reference to the clock original signal input to the memory;

FIG. 10 illustrates an operation for reading the memory performed in a circuit according to a fourth embodiment of the present invention, where the clock signal input to the memory is delayed with reference to the clock original signal input to the data-capture flip-flop circuit;

FIG. 11 illustrates an operation for writing into the memory performed in the circuit according to the fourth embodiment, where the clock signal input to the memory is delayed with reference to the clock original signal input to the data-capture flip-flop circuit;

FIG. 12 illustrates an operation for reading the memory performed in a circuit according to a fifth embodiment of the present invention, where the clock signal input to the data-capture flip-flop circuit is delayed with reference to the clock original signal input to the memory;

FIG. 13 illustrates an operation for writing into the memory performed in the circuit of the fifth embodiment, where the clock signal input to the data-capture flip-flop circuit is delayed with reference to the clock original signal input to the memory;

FIG. 14 illustrates an operation for reading the memory performed in a circuit according to a sixth embodiment of the present invention, where the clock signal input to the memory is delayed with reference to the clock original signal input to the data-capture flip-flop circuit;

FIG. 15 illustrates an operation for writing into the memory performed in the circuit according to the sixth embodiment, where the clock signal input to the memory is delayed with reference to the clock original signal input to the data-capture flip-flop circuit;

FIG. 16 illustrates an operation for reading the memory performed in a circuit according to a seventh embodiment of the present invention, where the clock signal input to the data-capture flip-flop circuit is delayed with reference to the clock original signal input to the memory;

FIG. 17 illustrates an operation for writing into the memory performed in the circuit of the seventh embodiment, where the clock signal input to the data-capture flip-flop circuit is delayed with reference to the clock original signal input to the memory;

FIG. 18 illustrates an operation for reading the memory performed in a circuit according to an eighth embodiment of the present invention, where the clock signal input to the memory is delayed with reference to the clock original signal input to the data-capture flip-flop circuit; and

FIG. 19 illustrates an operation for writing into the memory performed in the circuit according to the eighth embodiment, where the clock signal input to the memory is delayed with reference to the clock original signal input to the data-capture flip-flop circuit.

### DETAILED DESCRIPTION OF THE PREFERRED EMBODIMENTS

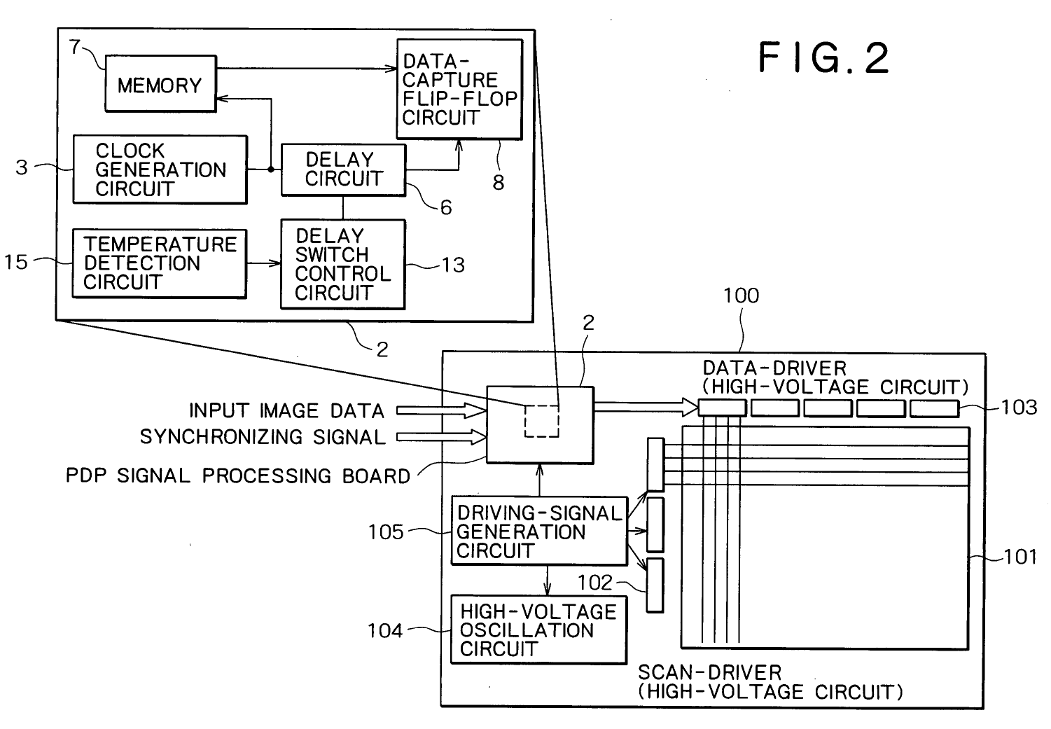

A first embodiment of the present invention will now be described with reference to FIGS. 2 to 7.

FIG. 2 is a block diagram of a plasma display panel (PDP) module 100. This PDP module 100 is shown as an example device having a memory access circuit according to the first embodiment mounted thereon. This PDP module 100 requires a large-capacity frame memory and functions as a large display device that can operate in a temperature range from 10 degrees Celsius below zero to 80 degrees Celsius and that has variations in initial settings on the power supply voltage of an LSI. The memory access circuit of the present invention can operate with stability when mounted on a large display device such as the above-described PDP.

As shown in FIG. 2, the PDP module 100 has a panel 101, scan drivers 102 and data drivers 103 for driving a plurality of pixels provided in matrix form on the panel 101, and a memory circuit 2. Both of these scan drivers 102 and the data drivers 103 are formed as high-voltage circuits. The PDP module 100 further includes a high-voltage oscillation circuit 104 and a driving signal generation circuit 105. This driving signal generation circuit 105 generates and supplies a driving signal to each of the drivers and drives the high-voltage oscillating circuit 104.

As shown in this drawing, in the memory circuit 2, data is input from a memory 7 to a data-capture flip-flop circuit 8. A clock original signal is generated by a clock generation circuit 3 and input to a delay circuit 6 and the memory 7. A delay clock signal delayed by the delay circuit 6 is input to the data-capture flip-flop circuit 8. A detection signal of a temperature detection circuit 15 for detecting the temperature of the PDP module 100 is input to a delay switch control circuit 13. Then, the delay switch control circuit 13 transmits a signal with a suitable delay amount to the delay circuit 6 based on the temperature of the PDP module 100. The delay circuit 6 controls the delay amount of a clock signal based on this signal.

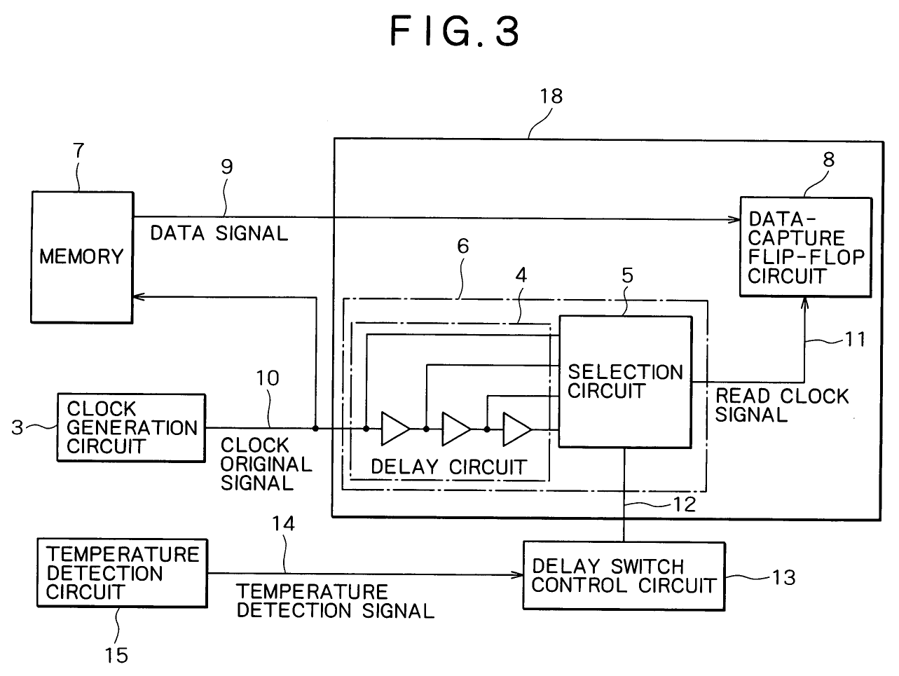

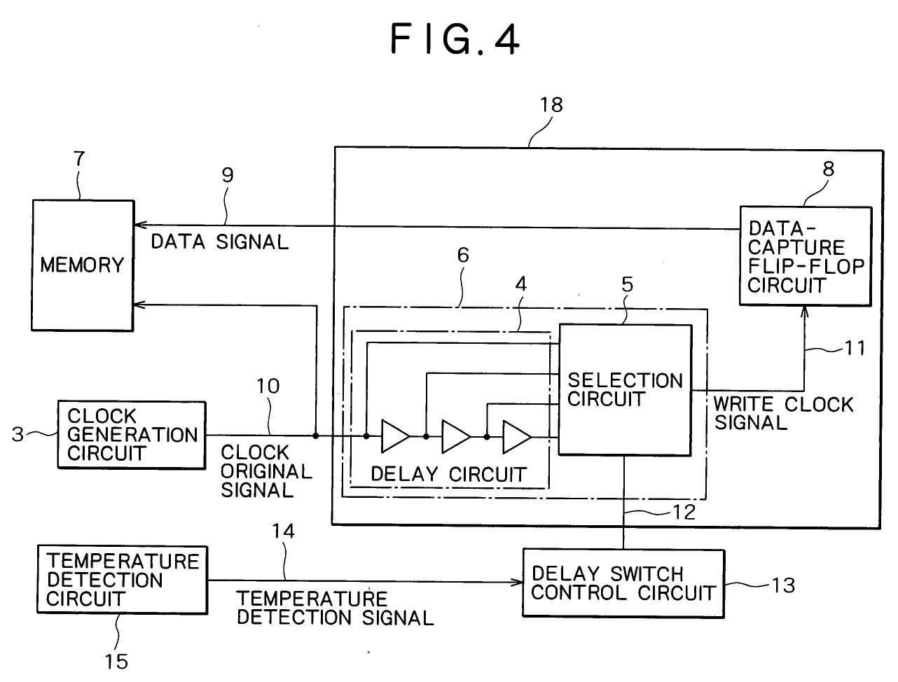

Each of FIGS. 3 and 4 is a block diagram further illustrating the configuration of this memory access circuit 2. As described above, the memory access circuit 2 has the clock generation circuit 3 for generating the clock original signal, the delay circuit 6, the memory 7, the data-capture flip-flop circuit 8, the temperature detection circuit 15, and the delay switch control circuit 13. The memory access circuit 2 may have a plurality of the temperature detection circuits 15.

The clock generation circuit 3 generates the clock original signal by shaping an oscillation signal output from a crystal oscillator connected to the LSI accessing the memory and multiplying the frequency of shaped signal, as required, for example. This clock original signal is transmitted to the memory 7 and the delay circuit 6 of the memory access circuit 18 through a clock original signal line 10.

A delay buffer 4 of the delay circuit 6 has a plurality of delay elements connected in series with one another. Since an output is obtained from each of these delay elements, signals with different delay times obtained by delaying the clock original signal from the clock generation circuit 3 by different times, that is, a plurality of clock signals with different delay times can be obtained, as output signals from the delay elements. These clock signals with different delay times are input to a selection circuit 5. Of course, the delay signals may be generated according to other methods without using the above-described delay buffer 4 having the plurality of delay elements.

The selection circuit 5 selects one of the delay signals from the delay buffer 4 and transmits it to the data-capture flip-flop circuit 8 through a signal line 11, as a read clock signal shown in FIG. 3 or a write clock signal shown in FIG. 4. Subsequently, the delay of the read clock signal and the write clock signal can be changed. The read clock signal determines the timing of storing data read from the memory 7. The write clock signal determines the timing of storing data written into the memory 7.

The delay circuit 6 includes the delay buffer 4 and the selection circuit 5, and delays the clock original signal input thereto via the signal line 10 and transmits it to the data-capture flip-flop circuit 8, thereby changing the delay time of the clock original signal.

The memory 7 is a clock synchronization memory. For example, the clock original signal is input to the memory 7 via the signal line 10 and data output from the memory 7 changes in synchronization with the clock original signal.

The data-capture flip-flop circuit 8 captures the data signal output from the memory 7 via the signal line 9 in synchronization with the read clock signal input thereto via the signal line 11.

The temperature detection circuit 15 detects the temperature of the PDP module 100, converts it to an electrical signal, and transmits this electrical signal to the delay switch control circuit 13 via a signal line 14, as a temperature detection signal. Then, the delay switch control circuit 13 transmits a delay switch signal used for selecting predetermined delay time to the selection circuit 5 via a signal line 12, based on the temperature of the PDP module.

The temperature detection circuit 15 may be provided directly on the LSI chip or the panel 101. Further, two or more temperature detection circuits 15 may be provided thereon. The accuracy of the detected temperature can be increased by providing a plurality of the temperature detection circuits 15, measuring temperatures at a plurality of positions, and averaging the detected temperatures, for example.

The temperature detection circuit 15 detects the temperature of a predetermined portion of the circuit substrate. Where the circuit substrate is provided in a case, the temperature detection circuit 15 detects the temperature of a predetermined place in the case.

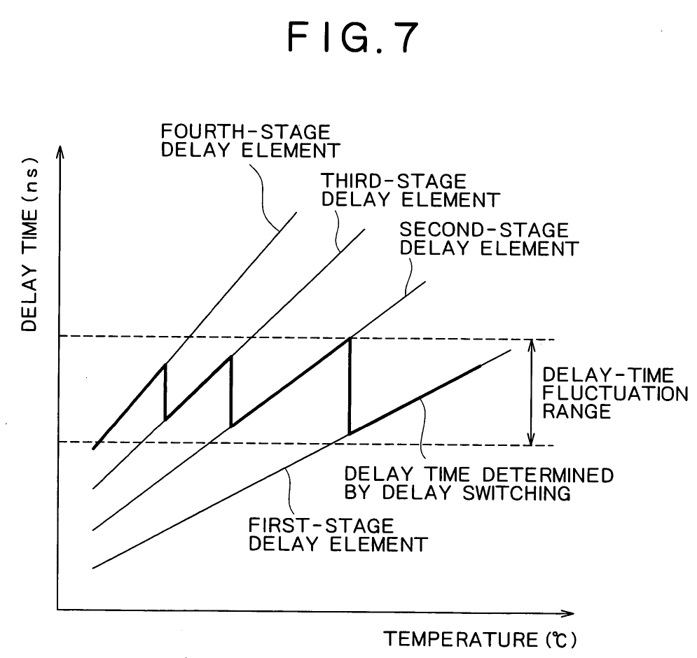

The operation of this embodiment will now be described. FIG. 7 illustrates an operation for changing the stage numbers of the delay elements according to the temperature. As shown in this drawing, the delay time of a signal output to the read clock signal line 11 changes, as the temperature changes, according to the functions of the temperature detection circuit 15, the delay switch control circuit 13, the delay circuit 4, and the selection circuit 5.

At this time, the delay switch control circuit 13 controls the delay circuit 6, based on the temperature detected by the temperature detection circuit 15, and changes the stage number of the delay elements 4. Subsequently, where the temperature changes from high to low, as shown by the thick line in this drawing, the fluctuation range of the delay time of the read clock signal line 11 decreases.

FIG. 3 illustrates an operation for reading the memory 7 performed in this circuit. The clock signal input to the data-capture flip-flop circuit 8 is delayed with reference to the clock original signal input to the memory 7.

Referring to this drawing, the operation for reading the memory 7 is achieved, where a data signal of the memory 7 operating according to the clock original signal is transmitted to the data-capture flip-flop circuit 8. That is to say, the operation for reading the memory 7 is correctly performed, where the change timing of the data signal and the read clock signal is within timing determined by the setup time and hold time of the data-capture flip-flop circuit 8.

FIG. 4 illustrates an operation for writing into the memory 7, where the clock signal input to the data-capture flip-flop circuit 8 is delayed with reference to the clock original signal input to the memory 7.

Referring to this drawing, the operation for writing into the memory 7 is achieved by transmitting the data signal to the memory 7 operating according to the clock original signal from the data-capture flip-flop circuit 8. That is to say, the operation for writing into the memory 7 is correctly performed, where the change timing of the data signal and a write clock signal is within timing determined by the setup time and hold time of the data-capture flip-flop circuit 8.

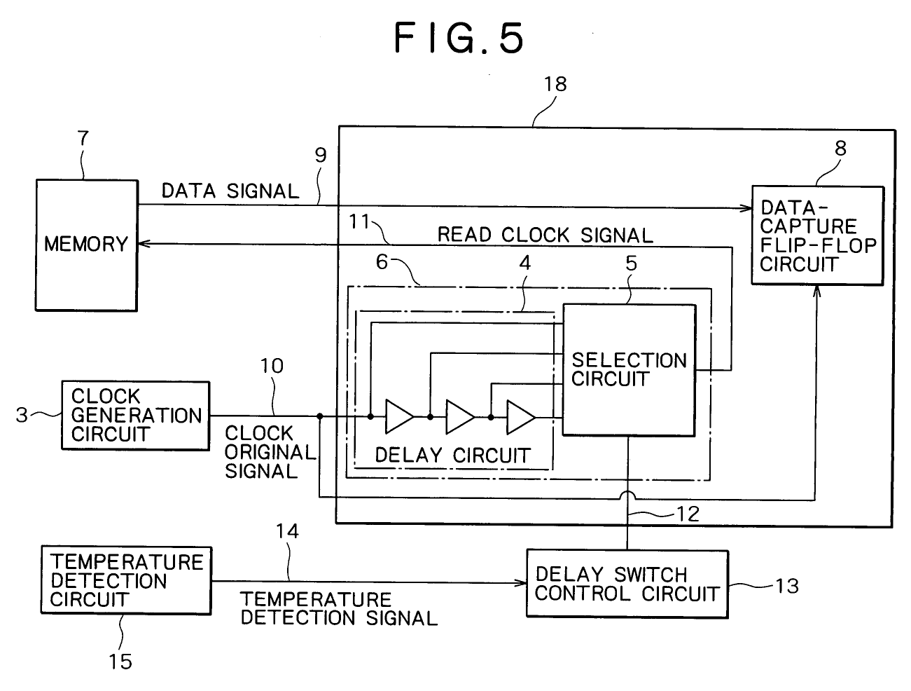

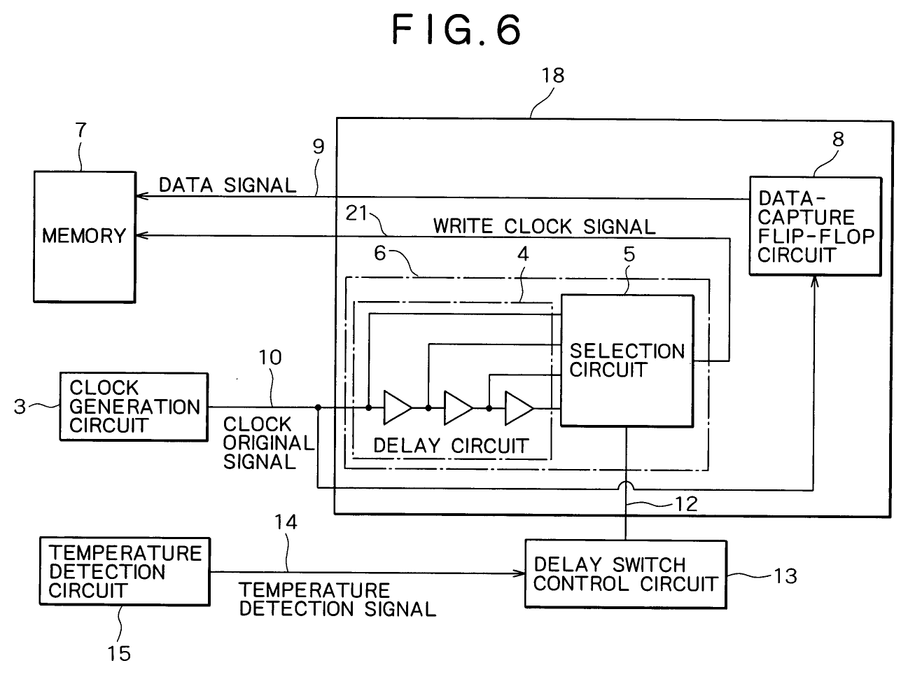

Each of FIGS. 5 and 6 is a block diagram illustrating a second embodiment of the present invention. This embodiment is different from the first embodiment in that the clock signal input to the memory 7 is delayed with reference to the clock original signal input to the data-capture flip-flop circuit 8.

Referring to FIG. 5, the operation for reading the memory 7 is achieved, where the data signal of the memory 7 operating according to a read clock signal is transmitted to the data-capture flip-flop circuit 8. More specifically, the data signal from the memory 7 is correctly read, where the change timing of the data signal and the clock original signal is within timing determined by the setup time and hold time of the data-capture flip-flop circuit 8.

FIG. 6 illustrates the circuit configuration of this embodiment. In this circuit, an operation is performed for writing into the memory 7, where a clock signal input to the memory 7 is delayed with reference to the clock original signal input to the data-capture flip-flop circuit 8.

Referring to this drawing, the operation for writing into the memory 7 is achieved by transmitting the data signal to the memory 7 from the data-capture flip-flop circuit 8, where the memory 7 operates based on a write clock signal. That is to say, the operation for writing into the memory 7 is correctly performed, where the change timing of the data signal and the clock original signal is within timing determined by the setup time and hold time of the data-capture flip-flop circuit 8.

Subsequently, the delay-time fluctuation range of the read clock signal is reduced, so as to be within specified timing of the data-capture flip-flop circuit 8. Therefore, the memory 7 can normally operate in a large temperature range, whereby the device can operate in the large temperature range.

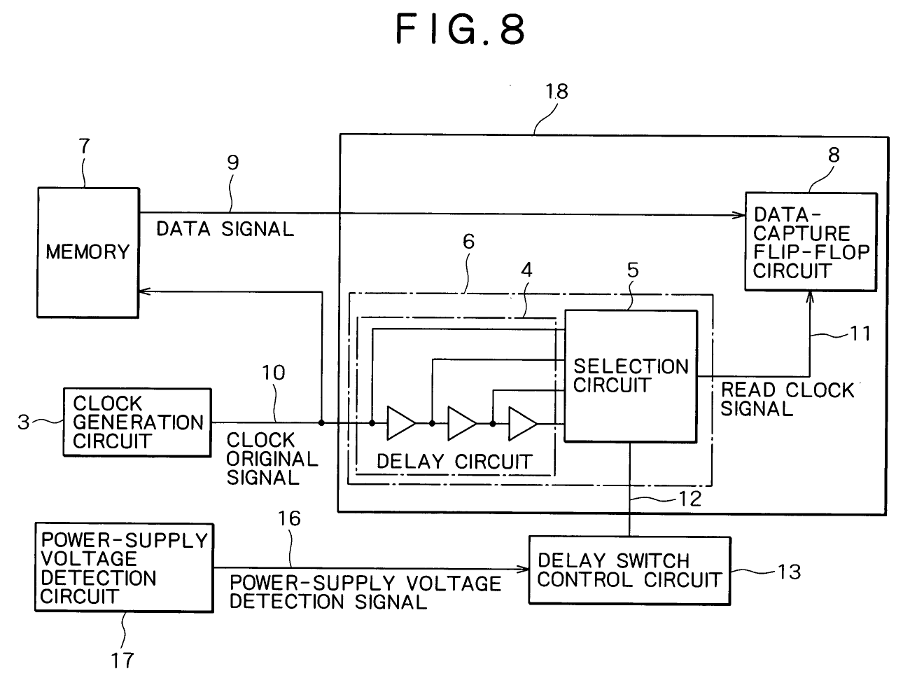

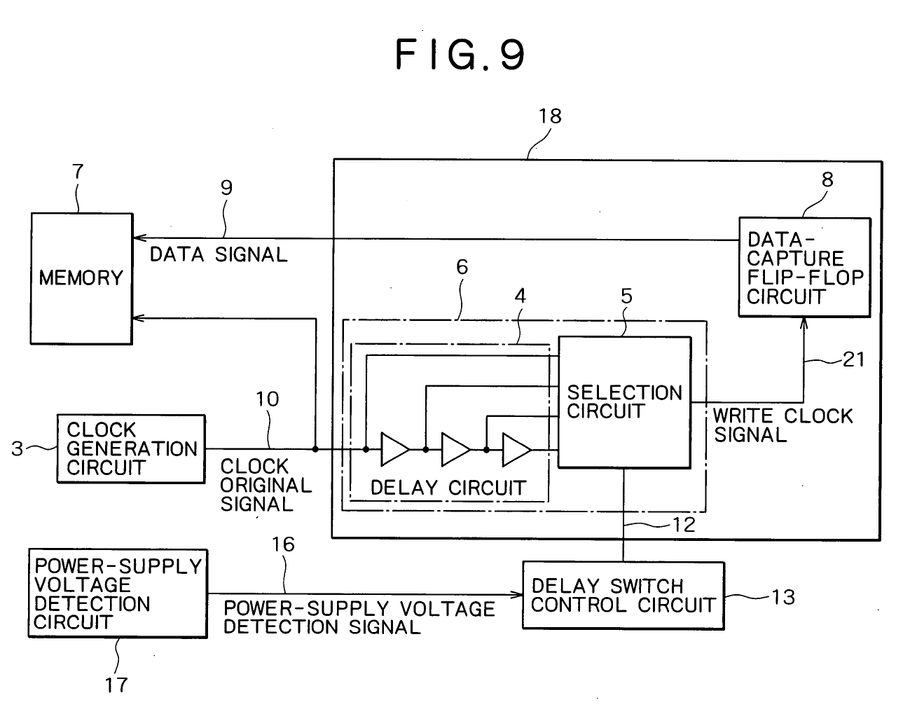

A third embodiment of the present invention will now be described with reference to FIGS. 8 and 9.

These drawings illustrate a circuit configuration according to this embodiment.

The transistor delay time and the read clock delay time change according to the change in the power-supply voltage of the memory access circuit.

Therefore, in this embodiment, a power-supply voltage detection circuit 17 is used in place of the temperature detection circuit of the first embodiment, whereby an increased power-supply voltage range can be obtained. A plurality of the power-supply voltage detection circuits 17 may be provided.

The power-supply voltage detection circuit 17 detects the power-supply voltage at a predetermined position on the circuit substrate. Where the circuit substrate is provided in the device, the power-supply voltage detection circuit 17 detects the voltage of a current flowing in the device at a predetermined position.

FIG. 8 illustrates an operation for reading the memory 7, where a clock signal input to the data-capture flip-flop circuit 8 is delayed with reference to the clock original signal input to the memory 7.

Referring to this drawing, the operation for reading the memory 7 is achieved by transmitting the data signal from the memory 7 operating according to the clock original signal to the data-capture flip-flop circuit 8. More specifically, the operation for reading the memory 7 is correctly performed, where the change timing of the data signal and the read clock signal is within timing determined by the setup time and hold time of the data-capture flip-flop circuit 8.

FIG. 9 illustrates an operation for writing into the memory 7, where the clock signal input to the data-capture flip-flop circuit 8 is delayed with reference to the clock original signal input to the memory 7.

Referring to this drawing, the operation for writing into the memory 7 is achieved by transmitting the data signal to the memory 7 operating according to the clock original signal from the data-capture flip-flop circuit 8. That is to say, the operation for writing into the memory 7 is correctly performed, where the change timing of the data signal and the write clock signal is within timing determined by the setup time and hold time of the data-capture flip-flop circuit 8.

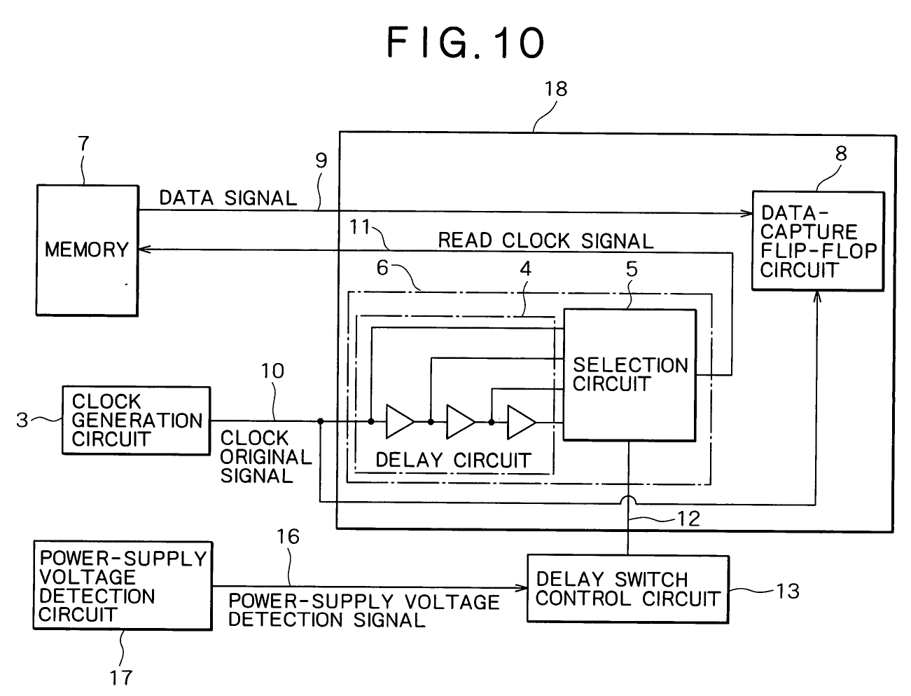

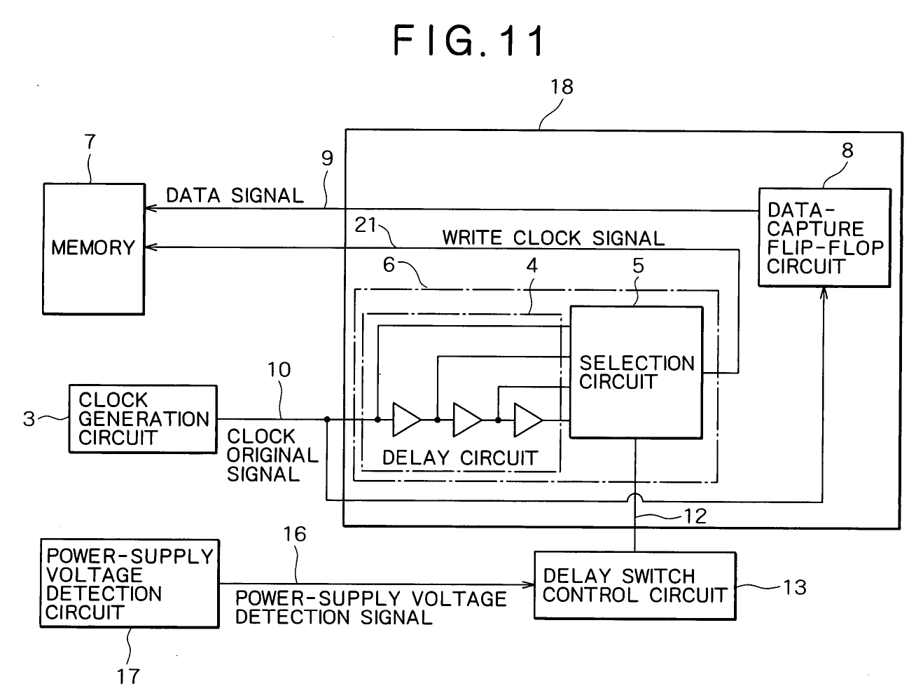

A fourth embodiment of the present invention will now be described with reference to FIGS. 10 and 11. The circuit configuration of this embodiment is different from that of the third embodiment in that the clock signal input to the memory 7 is delayed with reference to the clock signal input to the data-capture flip-flop circuit 8.

Referring to FIG. 10, the operation for reading the memory 7 is achieved by transmitting the data signal from the memory 7 operating according to the read clock signal to the data-capture flip-flop circuit 8. That is to say, the operation for reading the memory 7 is correctly performed, where the change timing of the data signal and the clock original signal is within timing determined by the setup time and hold time of the data-capture flip-flop circuit 8.

FIG. 11 illustrates an operation performed for writing into the memory 7, where the clock signal input to the memory 7 is delayed with reference to the clock signal input to the data-capture flip-flop circuit 8.

Referring to this drawing, the operation for writing into the memory 7 is achieved by transmitting the data signal to the memory 7 operating according to the write clock signal from the data-capture flip-flop circuit 8. That is to say, the operation for writing into the memory 7 is correctly performed, where the change timing of the data signal and the clock original signal is within timing determined by the setup time and hold time of the data-capture flip-flop circuit 8.

Subsequently, the delay-time fluctuation range of the read clock signal is reduced, so as to be within specified timing of the data-capture flip-flop circuit 8. Therefore, the memory 7 can normally operate in a large power-supply voltage range, whereby the device can operate in the large power-supply voltage range.

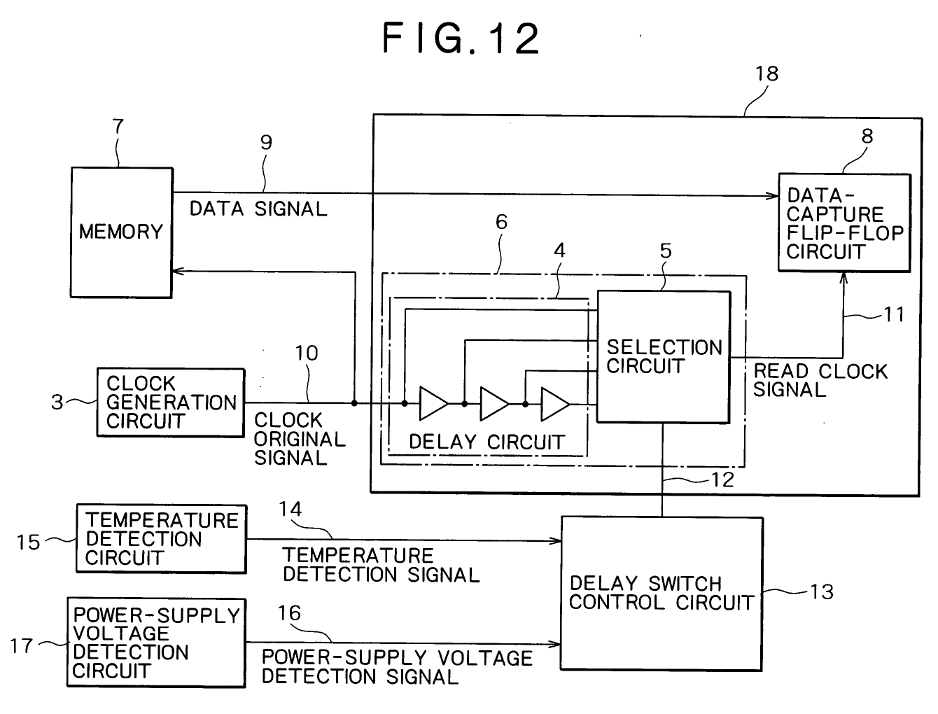

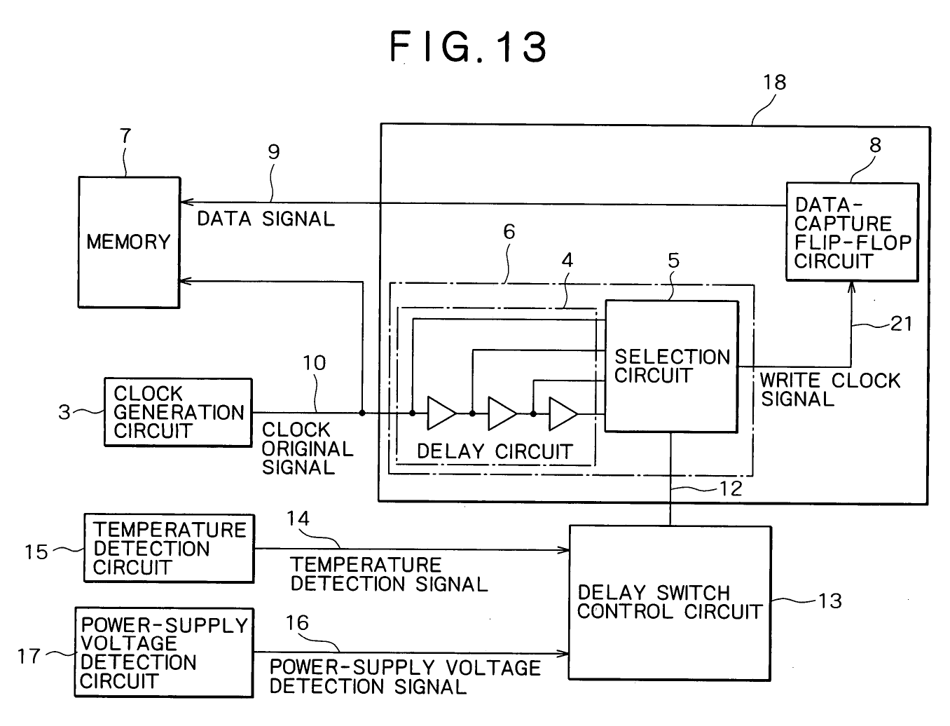

A fifth embodiment of the present invention will now be described with reference to FIGS. 12 and 13. These drawings illustrate an example circuit configuration according to this embodiment. This circuit includes both the temperature detection circuit 15 of the first embodiment and the power-supply voltage detection circuit 17 of the second embodiment. The delay amount of the read clock signal is switched according to a detected temperature and a detected power-supply voltage. A plurality of the temperature detection circuits 15 and a plurality of the power-supply voltage detection circuits 17 may be provided.

FIG. 12 illustrates an operation performed for reading the memory 7, where the clock signal input to the data-capture flip-flop circuit 8 is delayed with reference to the clock signal input to the memory 7.

Referring to this drawing, the operation for reading the memory 7 is achieved by transmitting the data signal from the memory 7 operating according to the clock original signal to the data-capture flip-flop circuit 8. More specifically, the operation for reading the memory 7 is correctly performed, where the change timing of the data signal and the read clock signal is within timing determined by the setup time and hold time of the data-capture flip-flop circuit 8.

In FIG. 13, an operation is performed for writing into the memory 7, where the clock signal input to the data-capture flip-flop circuit 8 is delayed with reference to the clock original signal input to the memory 7.

Referring to this drawing, the operation for writing into the memory 7 is achieved by transmitting the data signal to the memory 7 operating according to the clock original signal from the data-capture flip-flop circuit 8. That is to say, the operation for writing into the memory 7 is correctly performed, where the change timing of the data signal and the write clock signal is within timing determined by the setup time and hold time of the data-capture flip-flop circuit 8.

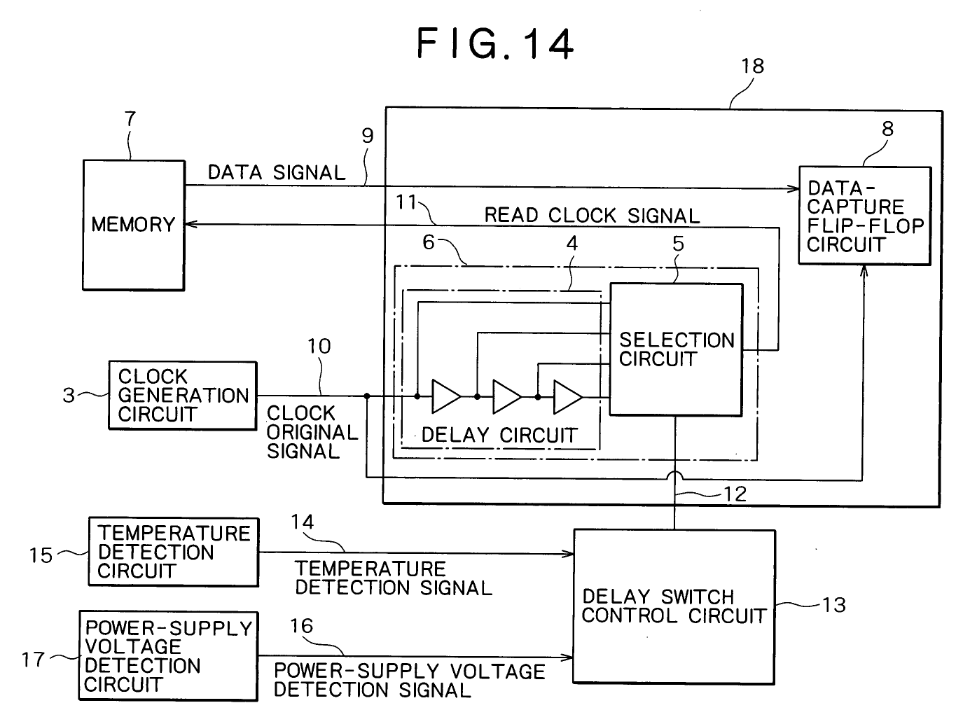

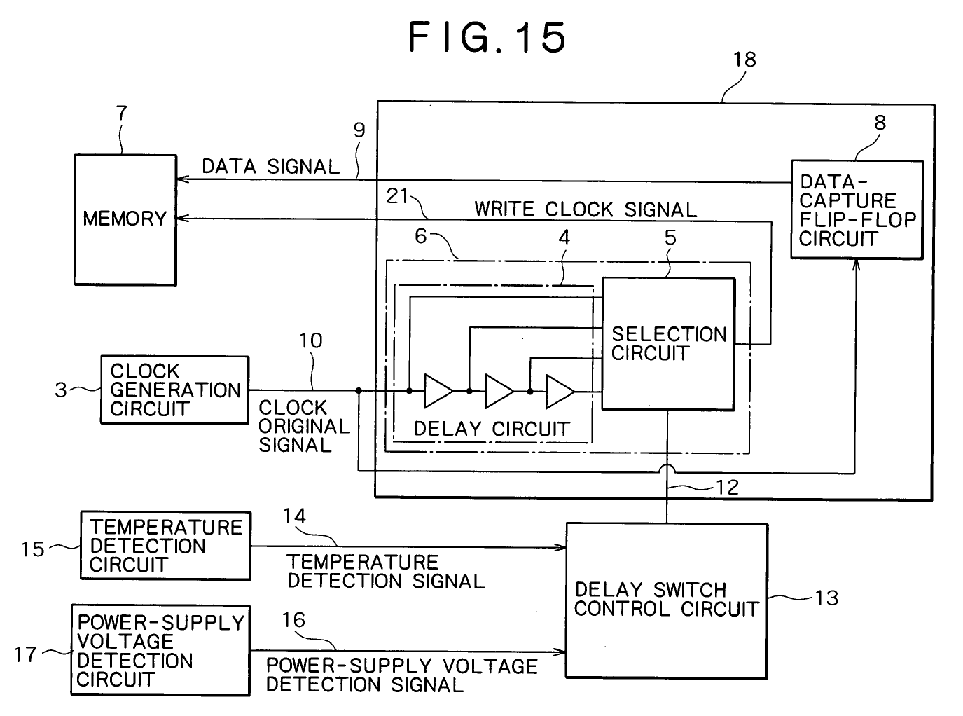

A sixth embodiment of the present invention will now be described with reference to FIGS. 14 and 15. The circuit configuration of this embodiment is different from that of the fifth embodiment in that the clock original signal input to the memory 7 is delayed with reference to the clock signal input to the data-capture flip-flop circuit 8.

Referring to FIG. 14, an operation for reading the memory 7 is achieved by transmitting the data signal from the memory 7 operating according to the read clock signal to the data-capture flip-flop circuit 8. That is to say, the operation for reading the memory 7 is correctly performed, where the change timing of the data signal and the clock original signal is within timing determined by the setup time and hold time of the data-capture flip-flop circuit 8.

FIG. 15 illustrates an operation performed for writing into the memory 7. In this case, the clock original signal input to the memory 7 is delayed with reference to the clock signal input to the data-capture flip-flop circuit 8.

Referring to this drawing, the operation for writing into the memory 7 is achieved by transmitting the data signal to the memory 7 operating according to the write clock signal from the data-capture flip-flop circuit 8. That is to say, the operation for writing into the memory 7 is correctly performed, where the change timing of the data signal and the clock original signal is within timing determined by the setup time and hold time of the data-capture flip-flop circuit 8.

Subsequently, the delay-time fluctuation range of the read clock signal is reduced, so as to be within specified timing of the data-capture flip-flop circuit 8. Therefore, the memory 7 can normally operate in a large power-supply voltage range, whereby the device can operate in a large temperature range and the large power-supply voltage range.

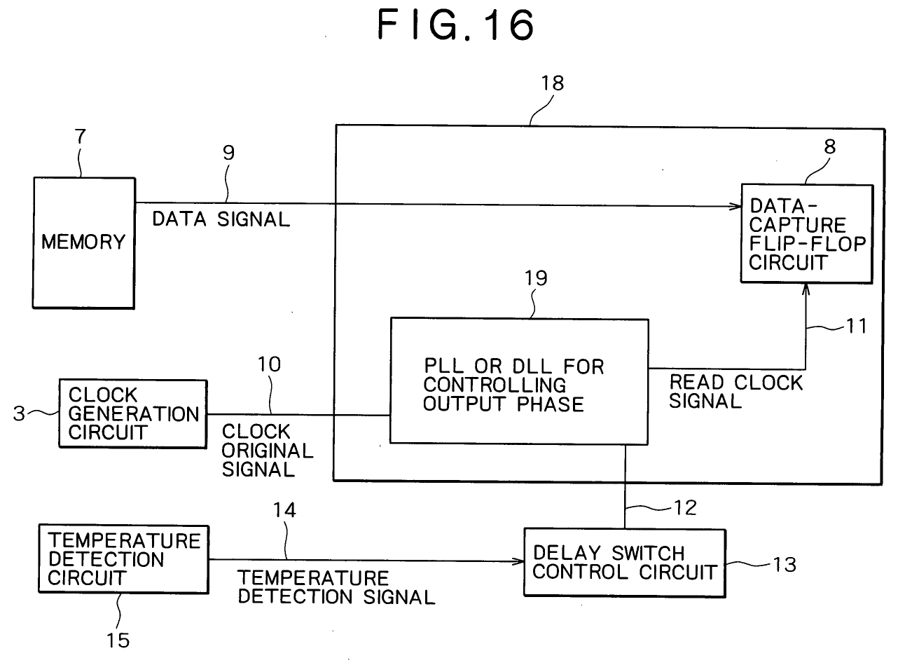

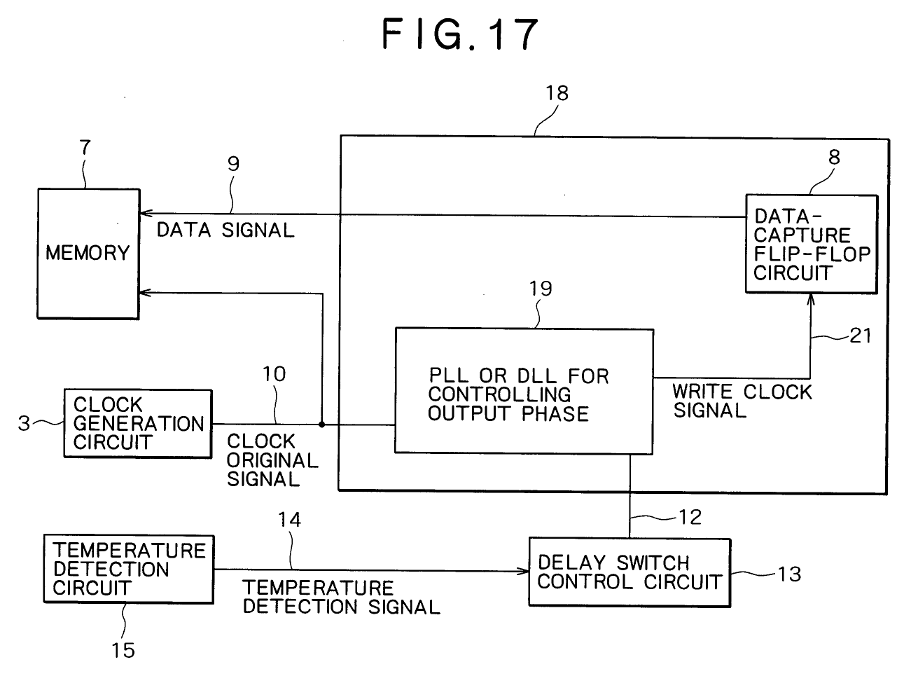

A seventh embodiment of the present invention will now be described with reference to FIGS. 16 and 17. Each of these drawings illustrates a circuit configuration of this embodiment.

In this embodiment, the delay circuit 6 is formed as a PLL circuit or a DLL circuit, where the phase of an output signal therefrom is adjustable.

FIG. 16 illustrates an operation performed for reading the memory 7, where the clock signal input to the data-capture flip-flop circuit 8 is delayed with reference to the clock signal input to the memory 7.

Referring to this drawing, the operation for reading the memory 7 is achieved by transmitting the data signal from the memory 7 operating according to the clock original signal to the data-capture flip-flop circuit 8. That is to say, the operation for reading the memory 7 is correctly performed, where the change timing of the data signal and the read clock signal is within timing determined by the setup time and hold time of the data-capture flip-flop circuit 8.

FIG. 17 illustrates an operation performed for writing into the memory 7, where the clock signal input to the data-capture flip-flop circuit 8 is delayed with reference to the clock original signal input to the memory 7.

Referring to this drawing, the operation for writing into the memory 7 is achieved by transmitting the data signal to the memory 7 operating according to the clock original signal from the data-capture flip-flop circuit 8. That is to say, the operation for writing into the memory 7 is correctly performed, where the change timing of the data signal and the write clock original signal is within timing determined by the setup time and hold time of the data-capture flip-flop circuit 8.

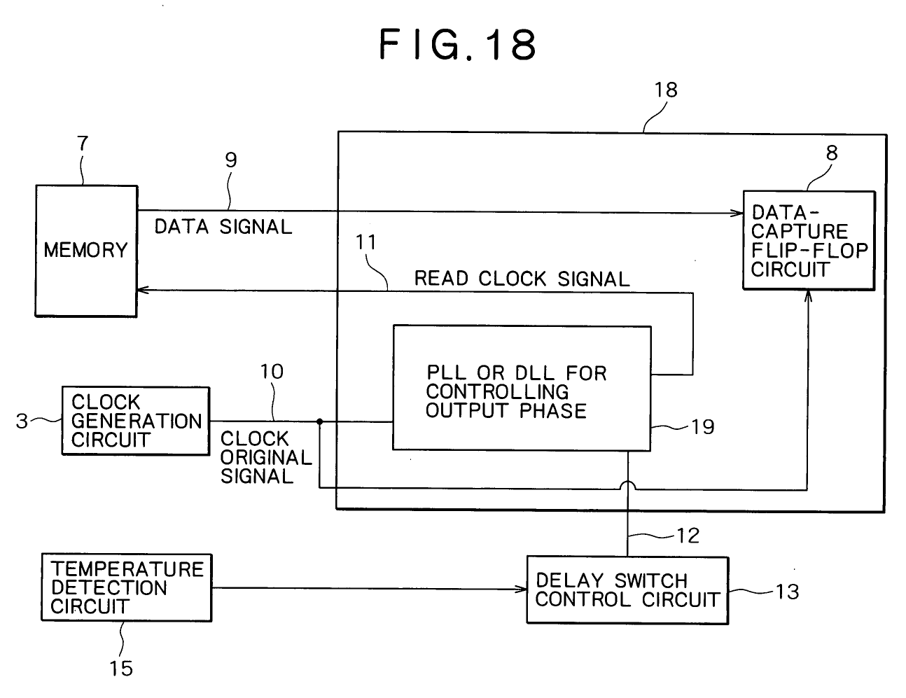

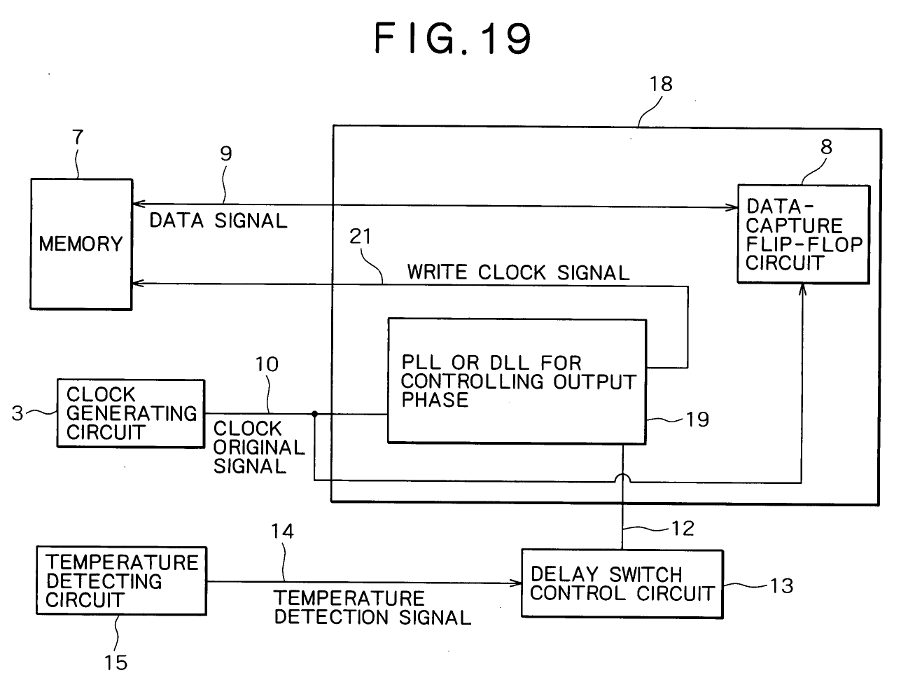

An eighth embodiment of the present invention will now be described with reference to FIGS. 18 and 19. The circuit configuration of this embodiment is different from that of the seventh embodiment in that the clock signal input to the memory 7 is delayed with reference to the clock signal input to the data-capture flip-flop circuit 8.

Referring to FIG. 18, the operation for reading the memory 7 is achieved by transmitting the data signal from the memory 7 operating according to the read clock signal to the data-capture flip-flop circuit 8. That is to say, the operation for reading the memory 7 is correctly performed, where the change timing of the data signal and the clock original signal is within timing determined by the setup time and hold time of the data-capture flip-flop circuit 8.

FIG. 19 illustrates an operation performed for writing into the memory 7, where the clock signal input to the memory 7 is delayed with reference to the clock signal input to the data-capture flip-flop circuit 8.

Referring to this drawing, the operation for writing into the memory 7 is achieved by transmitting the data signal to the memory 7 operating according to the write clock signal from the data-capture flip-flop circuit 8. That is to say, the operation for writing into the memory 7 is correctly performed, where the change timing of the data signal and the clock original signal is within timing determined by the setup time and hold time of the data-capture flip-flop circuit 8.

Subsequently, the delay-time fluctuation range of the read clock signal is reduced, so as to be within specified timing of the data-capture flip-flop circuit 8. Therefore, the memory 7 can normally operate in a large temperature range, whereby the device can operate in the large temperature range.

What is claimed is:

1. A memory circuit comprising:
a memory;
a delay circuit for generating a delay clock signal by delaying a reference clock signal;
at least one detection circuit for detecting a temperature of the memory or therearound, and/or a power-supply voltage of the memory or therearound; and
a control circuit for generating a control signal according to the temperature or the power-supply voltage detected by the detection circuit,
wherein a delay amount of the delay clock signal is controlled by the control signal.

2. A memory circuit according to claim 1, further comprising a data capture circuit for capturing data read from the memory and/or data written into the memory, wherein the memory and/or the data capture circuit operates in synchronization with the delay clock signal.

3. A memory circuit according to claim 1, wherein the delay circuit is formed as a PLL circuit or a DLL circuit.

4. A memory circuit according to claim 2, wherein the delay circuit is formed as a PLL circuit or a DLL circuit.

5. A device including a memory circuit according to claim 1, wherein image data output from the memory circuit is displayed.

6. A device including a memory circuit according to claim 2, wherein image data output from the memory circuit is displayed.

7. A device including a memory circuit according to claim 3, wherein image data output from the memory circuit is displayed.

8. A device including a memory circuit according to claim 4, wherein image data output from the memory circuit is displayed.

9. A device including a memory circuit according to claim 1 and a plasma display panel, wherein image data output from the memory circuit is displayed by the plasma display panel.

10. A device including a memory circuit according to claim 2 and a plasma display panel, wherein image data output from the memory circuit is displayed by the plasma display panel.

11. A device including a memory circuit according to claim 3 and a plasma display panel, wherein image data output from the memory circuit is displayed by the plasma display panel.

12. A device including a memory circuit according to claim 4 and a plasma display panel, wherein image data output from the memory circuit is displayed by the plasma display panel.

13. A method for operating a memory circuit including a memory, the method comprising the steps of:
generating a delay clock signal by delaying a reference clock signal;
detecting a temperature and/or a power-supply voltage of the memory; and
determining a delay amount of the delay clock signal according to the detected temperature and/or the detected power-supply voltage.

14. A method for operating a memory circuit including a memory, a first clock, and a second clock, the method comprising the steps of:
driving the memory in synchronization with the first clock;
capturing data read from the memory and/or data written into the memory in synchronization with the second clock;
detecting a temperature and/or a power-supply voltage of the memory or therearound; and
controlling a relative delay amount between the first clock and the second clock according to the detected temperature and/or the detected power-supply voltage.
